(19) United States
(12) Patent Application Publication
(10) Pub. No.: US 2009/0279575 A1
(43) Pub. Date: Nov. 12, 2009

(54) CARRIER SUBSTRATE FOR MICRO DEVICE PACKAGING

(75) Inventors: Eric C.E. van Grunsven, Someren (NL); Willem Hoving, Geldrop (NL); Anton P.M. van Arendonk, Mierlo (NL); Johannes W. Weekamp, Beek En Donk (NL); Olaf T.J. Vermeulen, Oss (NL); Marc A. de Samber, Lommel (BE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics, N.V., Eindhoven (NL)

(21) Appl. No.: 12/097,610

(22) PCT Filed: Dec. 13, 2006
(86) PCT No.: PCT/IB06/54828

§ 371 Date: Nov. 10, 2008

Related U.S. Application Data
(60) Provisional application No. 60/751,426, filed on Dec. 16, 2005.

(51) Int. Cl. H01S 3/10; H01L 21/50; H01S 3/04; H01S 5/00

(52) U.S. Cl. 372/22; 438/29; 257/E21.499; 372/34; 372/50.12

(57) ABSTRACT

A carrier substrate (100) with laser sources includes a transparent center substrate (20), an upper substrate (30) adhered to the center substrate having openings (40) formed therein to expose the center substrate on a first side, and a lower substrate (32) adhered to the center substrate on a second side opposite the first side and having openings (42) formed therein to expose the center substrate on the second side, the openings on the lower substrate corresponding to positions of the openings in the upper substrate. Frequency conversion elements (60) are disposed on the center substrate within the openings of the lower substrate. Laser dies (70) are aligned to the frequency conversion elements and coupled to the lower substrate to provide light though the frequency conversion elements and the center substrate during operation. Methods for fabrication are also disclosed.

This disclosure relates to electronic component packaging, and more particularly to a carrier module having a plurality of micro devices fabricated on or in a carrier substrate.

Micro devices such as integrated circuits, diodes and lasers may be manufactured in array-type setups. These set ups often require the placement of individual devices in a row or column on a printed wiring board or other carrier. The micro devices are often individually manufactured, and placed on the board one-by-one. This one-by-one placement results in tolerance and alignment problems.

It would be advantageous to provide a carrier where positioning and placement of micro devices is reliably performed. It would also be advantageous to employ the carrier to provide features needed for the operation of the micro devices.

A carrier substrate with laser sources includes a transparent center substrate, an upper substrate adhered to the center substrate having openings formed therein to expose the center substrate on a first side, and a lower substrate adhered to the center substrate on a second side opposite the first side and having openings formed therein to expose the center substrate on the second side. The openings on the lower substrate correspond to positions of the openings in the upper substrate. Frequency conversion elements are disposed on the center substrate within the openings of the lower substrate. Laser dies are aligned to the frequency conversion elements and coupled to the lower substrate to provide light though the frequency conversion elements and the center substrate during operation.

Methods for fabrication are also disclosed. For example, a method for fabricating a carrier substrate with laser sources includes bonding an upper substrate to a first side of a transparent center substrate and a lower substrate to a second side of the center substrate opposite the first side and forming openings to the center substrate through the upper and lower substrate such that openings correspond on opposite sides of the center substrate. A frequency conversion element is attached or grown to/on the center substrate on the first side in the openings. A laser die or dies are aligned to each frequency conversion element, and the laser dies are coupled to the lower substrate such that light from the laser dies is communicated through the frequency conversion element and the center substrate.

These and other objects, features and advantages of the present disclosure will become apparent from the following detailed description of illustrative embodiments thereof, which is to be read in connection with the accompanying drawings.

This disclosure will present in detail the following description of preferred embodiments with reference to the following figures wherein:

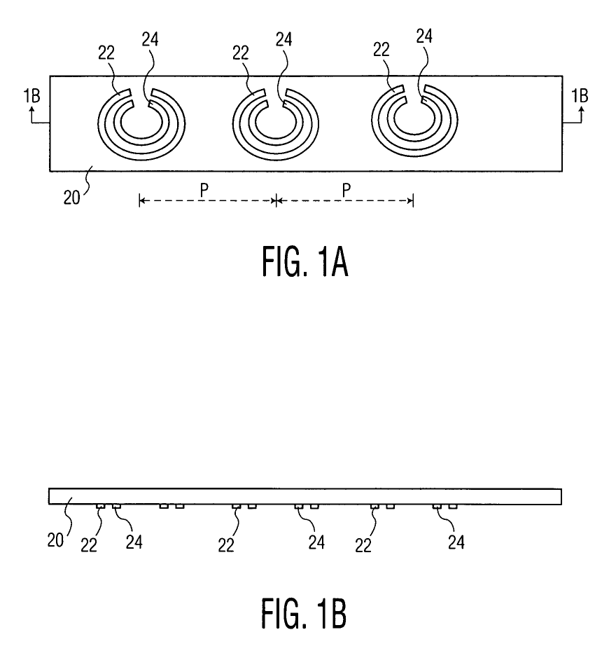

FIG. 1A is a bottom view of a transparent substrate having heaters and sensor components formed thereon;

FIG. 1B is a cross-sectional view taken at section line 1B-1B of FIG. 1A;

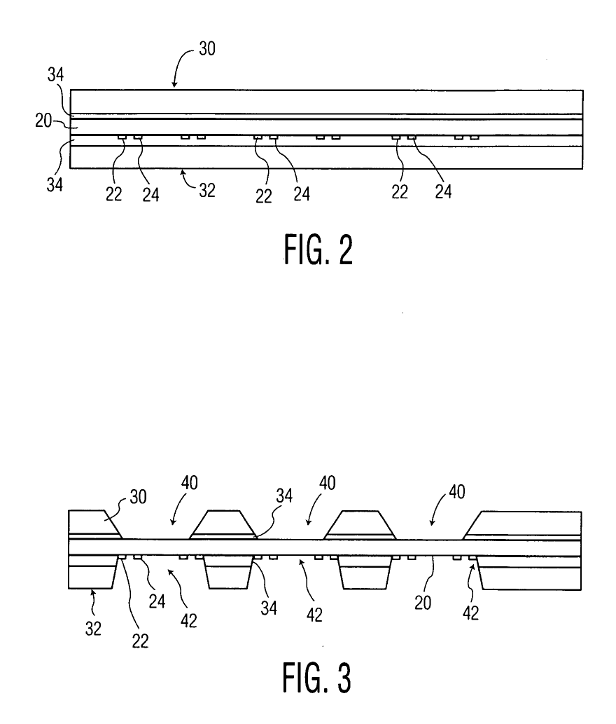

FIG. 2 is a cross-sectional view showing upper and lower substrates bonded to the center substrate;

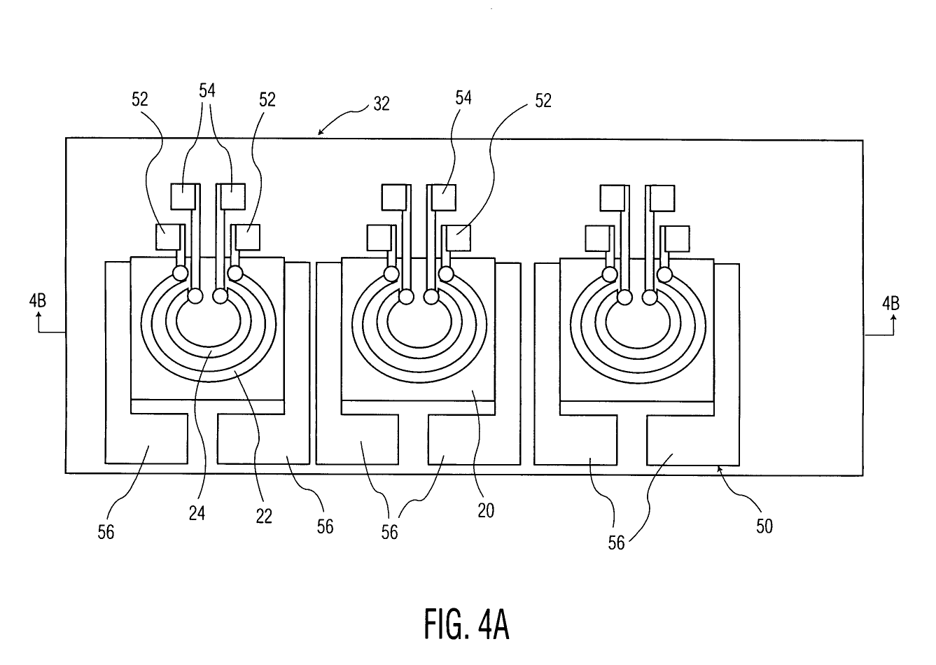

FIG. 3 is a cross-sectional view showing upper and lower substrates lithographically etched to open cavities down to the center substrate;

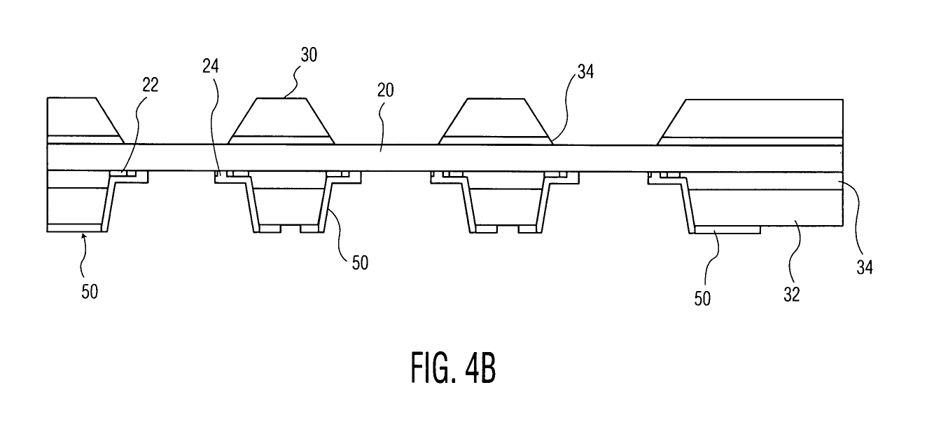

FIG. 4A is a bottom view showing a conductor patterned for connection lines for components of the carrier substrate;

FIG. 4B is a cross-sectional view taken at section line 4B-4B of FIG. 4A;

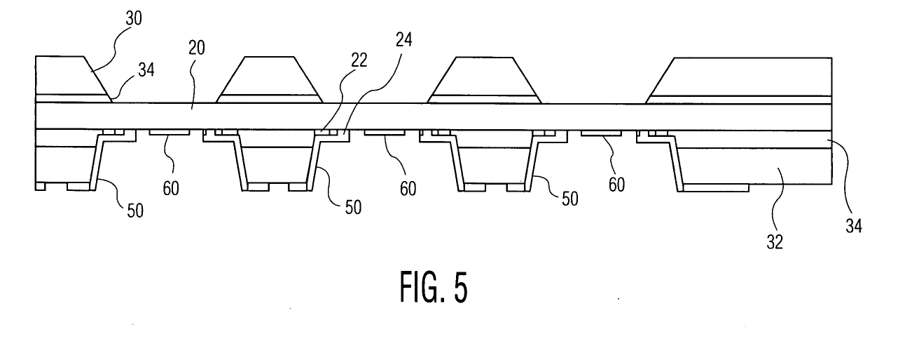

FIG. 5 is a cross-sectional view showing frequency conversion elements placed in contact with the center substrate;

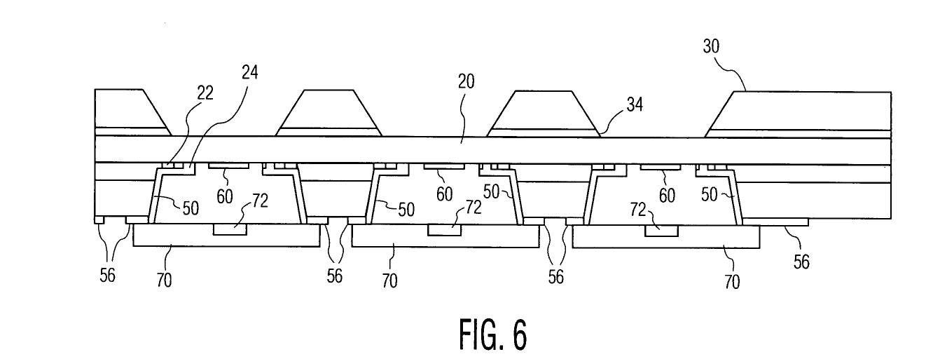

FIG. 6 is a cross-sectional view showing laser dies placed in alignment with the frequency conversion elements;

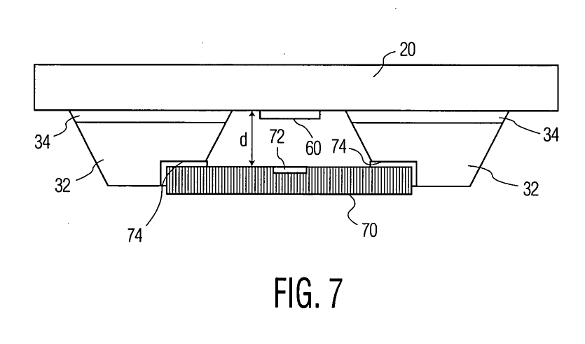

FIG. 7 is a cross-sectional view showing details of an alternate embodiment for locating and aligning the laser dies;

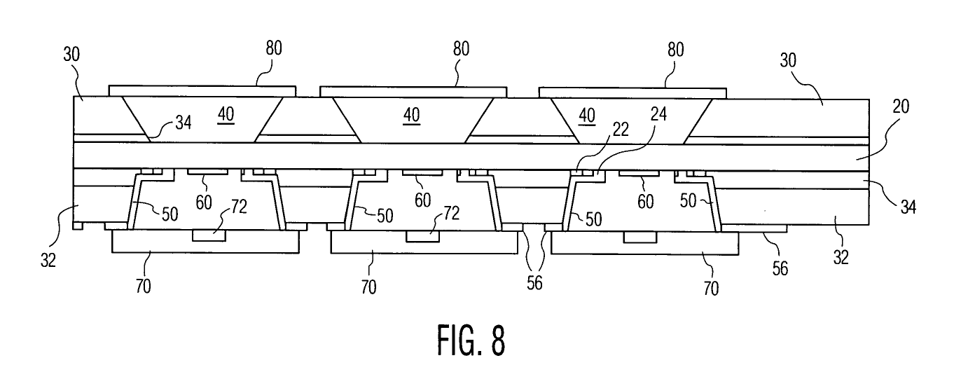

FIG. 8 is a cross-sectional view showing frequency selective mirrors (e.g., Bragg mirrors) placed on the carrier substrate;

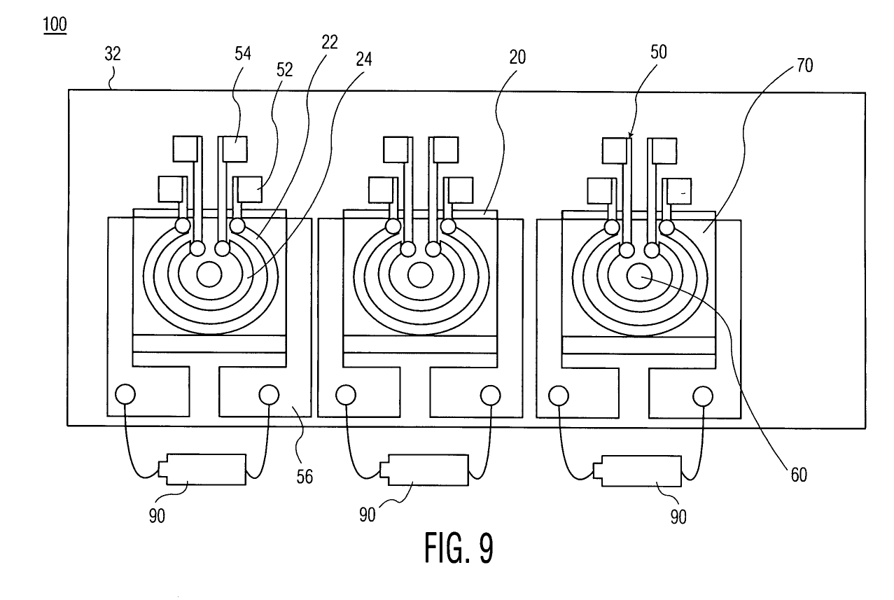

FIG. 9 is a bottom view showing power sources connected to the laser dies;

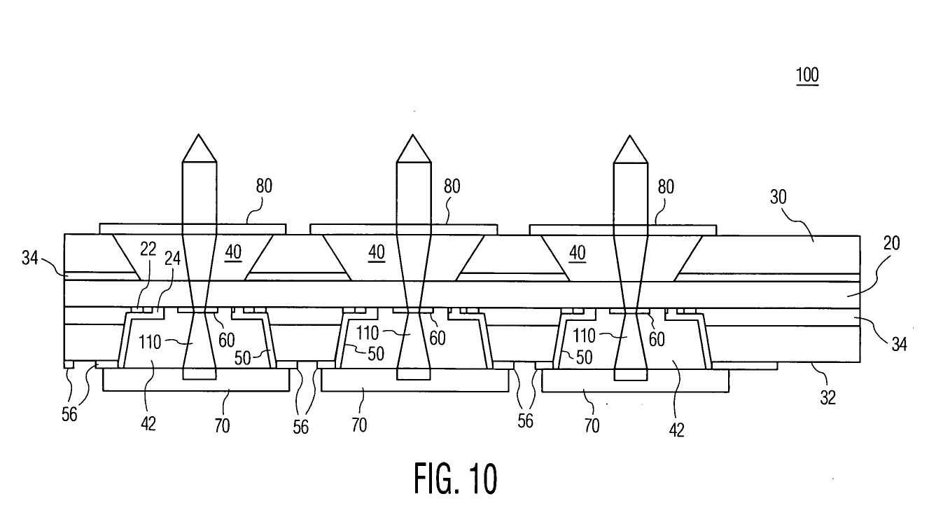

FIG. 10 is a cross-sectional view showing laser light being emitted during operation of the laser sources; and

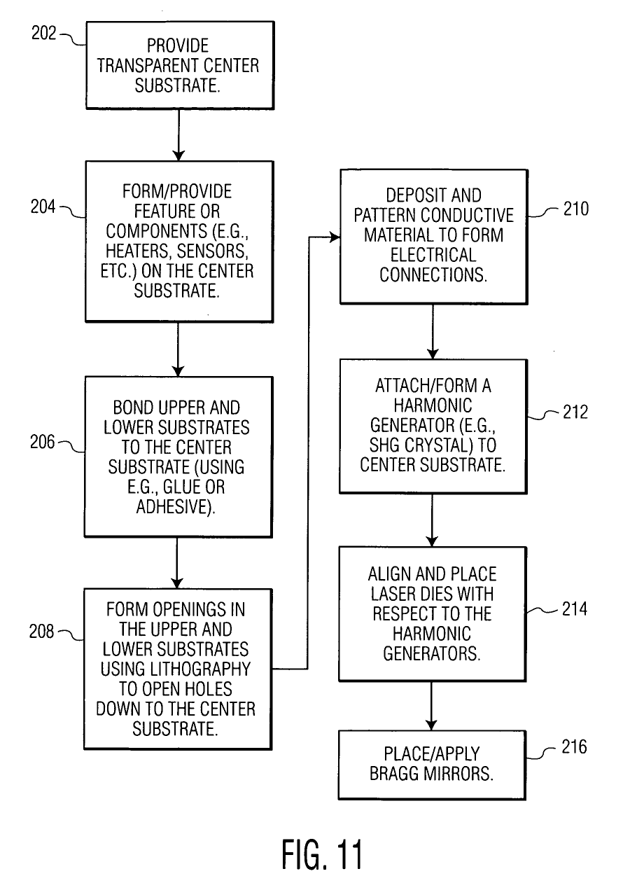

FIG. 11 is a flow diagram showing steps for fabricating a carrier substrate in accordance with an illustrative embodiment of the present invention.

The present disclosure describes a carrier substrate employed for mounting and incorporating a plurality of micro devices. The carrier substrate is processed using photolithography and therefore has the advantage of high precision placement and control of device sizes and pitch. In one particularly useful embodiment, a carrier substrate is provided for a miniaturized multi-color laser unit. The manufacture of a miniaturized multi-color laser unit may be formed by process steps using lithography and thin film technology. In one example, the parts may include, e.g., lasers, frequency conversion elements (e.g., second-harmonic generation (SHG) crystals), and Bragg-mirrors. These parts of a basic laser source module are formed by successive layers on a “smart” carrier substrate, using silicon substrates and thin film fabrication techniques. The parts are thus assembled very precisely and close to each other. This wafer-level processing enables the generation of many modules on one plate in one process flow, presenting opportunities for cost and price reduction.

It should be understood that the present invention will be described in terms of laser modules; however, the teachings of the present invention are much broader and are applicable to any components that can be mounted on, positioned on or otherwise placed on a carrier substrate. Embodiments described herein are preferably located using lithography and hence are located in accordance with the applicable accuracy of the lithographic process selected. It should be noted that photolithographic processing is preferred but merely illustrative. Other processing techniques may also be employed.

It should also be understood that the illustrative example of the laser modules may be adapted to include additional electronic components. These components may be formed integrally with the substrate carrier or mounted on the substrate carrier or other components. In addition, laser modules and their components may vary depending on the application and the laser module design. The elements depicted in the FIGS. may be implemented in various combinations of hardware and provide functions which may be combined in a single element or multiple elements.

The following FIGS. depict illustrative processing steps to form a substrate carrier with a plurality of laser modules integrated therewith. Referring now to the drawings in which like numerals represent the same or similar elements and initially to FIG. 1A, a substrate 20 includes a transparent material (e.g., transparent to laser light) such as glass or doped glass. The substrate 20 may include a material having a defined index of refraction. Substrate 20 preferably includes a material with sufficient integrity and strength to function as a carrier for packaging a plurality of elements or devices. The top and bottom surfaces of transparent substrate 20 may have specific optical coatings to reduce the transmission losses of laser light. To improve the characteristics or the stability of the system, a heater 22 is formed or adhered to the surface of substrate 20.

Heater 22 may include a resistive material to generate heat to substrate 20 to maintain a stable reproducible temperature of substrate 20 at the position where the frequency conversion element 60, see FIG. 5, will be mounted later. A sensor 24 may be formed or adhered to substrate 20 to provide a feedback measure for heater 22 (to control when heater is on or off in accordance with a measurement comparison to a set point temperature). Heater 22 and sensor 24 are preferably formed by deposition of materials, and patterning the deposited material using photolithography and etching. Other methods may also be employed, e.g., the heater 22 and sensor 24 may be prefabricated and adhered to substrate 20 using glue or other adhesive.

Referring to FIG. 1B, a cross-sectional view taken at section lines 1B-1B of FIG. 1A shows heaters 22 and sensors 24 formed on a surface of substrate 20. Since lithography may be preferably employed in positioning the heaters 22 and sensors 24, the pitch, p (FIG. 1A), between these devices is within the precise tolerances provided by the lithographic process.

Referring to FIG. 2, substrates 30 and 32 are bonded to substrate 20 using, e.g., an adhesive or glue 34. Substrates 30 and 32 are preferably formed from silicon, and more preferably from monocrystalline silicon, although other substrate materials may be employed. Substrates 30 and 32 may include integrated elements, such as electronic components, transistors, passive elements, optical elements or any other structures or devices. The glue 34 bonds the substrate 30 and 32 to substrate 20. Glue 34 may be cured by heating the sub-assembly. Glue 34 may include a polymeric material, such as BCB (BenzoCycloButene), which is capable of being etched as will be described in subsequent steps. Glue 34 is uniformly distributed to provide a consistent thickness across substrate 20 (on both sides). The thickness of the glue 34 need not be the same on both sides of the substrate 20.

After bonding, the substrates 30 and 32 are planarized. This may include mechanical polishing of the substrate 30 and 32 to provide very plane/smooth parallel surfaces on externally opposite sides of substrate 20.

Referring to FIG. 3, using photolithography, a resist is formed on the surfaces of substrate 30 and 32 and patterned to form an etch mask. The etch mask is used to protect portions of substrates 30 and 32 while removing other portions. Substrates 30 and 32 and glue 34 are etched to form cavities 40 and 42. The etching may include a dry or wet etch selective to the material of substrate 20 and heater 22 and sensor 24 materials. The etching process may be performed in steps. For example, one etching process may be to etch substrates 30 and 32 and one etch process to etch glue 34. Since lithography is employed, the cavities 40 and 42 are centered over heater and sensor sites with lithographic precision.

Referring to FIG. 4A, a bottom view of substrate 32 shows conductor or metal 50 deposited and patterned to provide connections to heaters 22 and sensors 24. Conductor or metal 50 is deposited over a surface of substrate 32 and over heaters 22 and sensors 24 and exposed portions of substrate 20. A resist is deposited over metal 50 and patterned using lithography. The resist is used as an etch mask to remove portions of metal 50 to form heater connections 52, sensor connections 54, and laser die connections 56. Other component connections and components may also be formed using metal 50. Metal 50 may include any conductive material including doped polysilicon, copper, gold, silver, aluminum, alloys, or another conductive material. Etching of metal 50 is selective to substrate 20, heater 22 and sensor 24 materials. In an alternate embodiment, a mask layer may be employed, which is etched using lithography. The mask layer would then be employed to mask the metal 50 for etching. FIG. 4B shows a cross-sectional view taken at section line 4B-4B in FIG. 4A.

Referring to FIG. 5, a frequency conversion element (FCE) 60 is installed within the area of the sensor 24 on substrate 20. In one embodiment, the frequency conversion element 60 is fabricated separately from the carrier substrate and applied using bonding, adhesive or thermosonic bonding. In an alternate embodiment, the frequency conversion element 60 is grown on substrate 20. This may include masking other surfaces with a patterned resist or mask layer and growing the frequency conversion element 60 from substrate 20 by epitaxial deposition. The frequency conversion elements 60 preferably are second-harmonic generation crystals (SHG), such as KTP and PPLN, which are used in frequency-doubled lasers. The elements can also be up-conversion phosphors or down-conversion phosphors. Generally speaking, the element 60 can be any material that has the property to generate, frequency-shift, amplify or modulate light, such as, for example, double tungstate KY(WO₄)₂ (=KYW) which is a robust optical material with good heat conductivity. This KYW can be doped up to 100% (by replacement of the Y³⁺ions) with rare-earth ions such as Yb³⁺, Nd³⁺, Er³⁺, Tm³⁺, and Ho³⁺ thus acting as a thin film color conversion layer. Other host materials can also be used, e.g., fluoride glass or ZBLAN glass (a standard fluozirconate glass system with composition ZrFM4-BaF2-LaF3-AlF3-NaF).

The placement of the element (e.g., SHG crystal) 60 may include a large tolerance range since the SHG crystal can be aligned with the laser dies that will be installed later in the process. This improves ease of manufacture and reduces cost and time, among other things.

If frequency doubling crystals are employed for frequency conversion elements 60 (FIG. 5) elements, an optimum length (along the light path) of the crystals for optimum light conversion may be of the order of several millimeters (e.g., 3-5 mm). This may have implications for the thickness of the stack of the device. For this reason, shaped holes may be formed in the center substrate 20 in which the elements 60 (e.g., crystals) may be mounted. The substrate 20 may include shaped holes (not shown) to insert these or other optical elements for color conversion or beam shaping. These holes may be formed in advance of assembly or as part of a processing step. Other adaptations may also be included.

Referring to FIG. 6, laser dies 70 are installed and connected to laser die connections 56. Laser dies 70 may be aligned to elements (SHG crystals) 60 by viewing a portion 72 of the laser die 70, which emits light through substrate 20. By viewing laser dies 70 through substrate 20, alignment between SHG crystals 60 and dies 70 may be accurately performed. Laser dies 70 may be moved to fine tune the alignment between crystals 60 and dies 70. In this regard, laser connections 56 may be fabricated to provide a large area to adjust the laser dies 70 to provide the opportunity for alignment.

In an alternate embodiment, notches or landings 74 as shown in FIG. 7 may be provided to easily define positions for laser dies 70 to fit into. The laser die 70 can also be mounted on a special sub-mount for better thermal management or easy alignment. In addition, the distance, d, between laser die 70 and substrate 20 may be accurately controlled. Some adjustment may be permitted for alignment of laser dies 70 with SHG crystals 60 by extending the landings 74 further into substrate 34, alternatively the distance may be increased by putting a spacer between substrate 32 and the laser die 70, or sub-mount carrying the laser die 70. Laser dies 70 are separately fabricated components which generate laser light to be passed through SHG crystals 60 and substrate 20, as will be described herein. Preferred laser types may include vertical emitting lasers (VCSELs, Vertical Cavity Surface Emitting Lasers). Also planar emitting lasers (EELs, Edge Emitting Lasers) can be used that are mounted perpendicular to a laser sub-mount.

Referring to FIG. 8, Bragg mirrors or gratings 80 are mounted across cavities 40 opposite laser dies 70. Alignment of the mirrors 80 is not critical along the plane, and the mirrors 80 need only span the gap formed by cavities 40. The angular position of the Bragg mirrors 80 has a small tolerance window which is secured by the planar structure of the substrates and can be optimized, if needed, during the assembly process or afterwards using a fine-adjustment method. Bragg mirrors 80 may be secured in place by glue or adhesive. It should be understood that laser dies 70, SHG crystals 60 and mirrors 80 may be replaced with other components or additional components may be added. Some examples include the following. Mirrors 80 may be combined with a lens structure or other optical component for additional shaping of the beam. Laser dies 70 may be replaced with other optical sources, such as high-power Light-Emitting Diodes (LEDs), resonant-cavity LEDs and any other solid-state light source. SHG crystal 60 may be replaced by an optical beam shaping device, a gating device, e.g., a shutter, or integrated devices that reduce speckles from the laser beam, etc. and combinations thereof.

One illustrative application of the laser light source manufactured according to this disclosure includes an extremely compact light-engine used as a visible light source inside a miniature laser projector. Other applications and structures are also contemplated.

Referring to FIG. 9, a module or carrier substrate 100 is illustratively shown. Module 100 may be employed as a multi-color laser source(s). Module 100 includes laser sources (dies) 70, which are aligned and positioned with lithographic tolerances and accuracy. Connections 52, 54 and 56 may be connected to other components to permit the module 100 to interface with other modules or power sources 90. Although not shown, conductor 50 may be patterned to form a bus, landing position for other components or any other conductive structure or device. Components may be soldered to otherwise connect to patterned portions of conductor 50 as though substrate 34 were a printed wiring board.

In the embodiment shown, power sources 90 are connected to laser die connections 56 to provide power to laser dies 70. Other components that may be included on module 100 may include multiplexing devices, controller devices, triggering or timing devices, power on/off switches, or any other device that contributes to the application for which module 100 is designed.

It should be understood that module 100 may be fabricated as a stand-alone device or a plug-in module to a larger system. Although three laser sources are depicted, module 100 may be modified to provide fewer or greater numbers of positions for laser sources, and the laser sources may be positioned in a two dimensional array.

Referring to FIG. 10, in operation, laser dies 70 are activated and receive power to generate light as a second-harmonic laser. In operation, a fundamental beam 110 is directed through second-harmonic generator SHG 60 where a portion of the fundamental beam is converted to a secondary beam, in this instance, a second-harmonic beam. The fundamental beam from SHG 60 is reflected by mirror 80 back through the SHG element 60 where a further portion of the fundamental beam is converted to a second-harmonic beam. Mirror 80 then transmits the second-harmonic beam pulse outside the cavity 40 for end use. Each laser die 70 may produce light at different wavelengths (colors), this may impact the size (thicknesses), type and features of components (e.g., SHG crystal 60 may have a different thickness or crystal type, etc.). Heaters 22 and sensors 24 may be employed to alter the operating conditions by, for example, maintaining a stable temperature of substrate 20 and crystal 60 in the area where light passes through. Other features and conditions may be added as well.

Referring to FIG. 11, a method for fabricating a carrier substrate with laser sources is illustratively shown in accordance with one exemplary embodiment. In block 202, a transparent center substrate is provided, which may be preprocessed with positioning holds, grooves or the like. In block 204, features and components may be formed or patterned on/in the center substrate. For example, heaters and sensors may be formed on one side of a transparent center substrate. In block 206, lower and upper substrates are bonded to the center substrate. The bonding may include a low-temperature fusion bonding process or applying an adhesive or glue and curing the adhesive or glue.

In block 208, openings are formed down to the center substrate through the upper and lower substrates such that openings correspond on opposite sides of the center substrate. The openings are preferably etched in accordance with a photolithographic resist pattern to expose both sides of the center substrate. The openings in the upper and lower substrates advantageously include a pitch or a placement having lithographic tolerances on the positions of the openings. In block 210, a conductive material is deposited and patterned to enable electrical connections to the heaters, the sensors, laser dies, etc. In block 212, a frequency conversion element, such as a SHG crystal, is attached or formed on the center substrate in the openings.

In block 214, laser dies are aligned to each frequency conversion element and coupled to the lower substrate such that light from the laser dies is communicated through the frequency conversion element and the center substrate during operation. The aligning may include viewing a laser die through the center substrate and the frequency conversion element to align the laser die to the frequency conversion element. In block 216, mirrors, such as Bragg mirrors are applied to the upper substrate over the openings in the upper substrate.

In interpreting the appended claims, it should be understood that:
a) the word “comprising” does not exclude the presence of other elements or acts than those listed in a given claim;
b) the word “a” or “an” preceding an element does not exclude the presence of a plurality of such elements;
c) any reference signs in the claims do not limit their scope;
d) several “means” may be represented by the same item or hardware or software implemented structure or function; and
e) no specific sequence of acts is intended to be required unless specifically indicated.

Having described preferred embodiments for systems and methods for a carrier substrate for micro device packaging (which are intended to be illustrative and not limiting), it is noted that modifications and variations can be made by persons skilled in the art in light of the above teachings. It is therefore to be understood that changes may be made in the particular embodiments of the disclosure disclosed which are within the scope and spirit of the embodiments disclosed herein as outlined by the appended claims. Having thus described the details and particularity required by the patent laws, what is claimed and desired protected by Letters Patent is set forth in the appended claims.

1. A carrier substrate (100) with laser sources, comprising:
a transparent center substrate (20);
an upper substrate (30) adhered to the center substrate having openings (40) formed therein to expose the center substrate on a first side;
a lower substrate (32) adhered to the center substrate on a second side opposite the first side and having openings (42) formed therein to expose the center substrate on the second side, the openings on the lower substrate corresponding to positions of the openings in the upper substrate;
frequency conversion elements (60) disposed on the center substrate within the openings of the lower substrate; and
laser dies (70) aligned to the frequency conversion elements and coupled to the lower substrate to provide light though the frequency conversion elements and the center substrate during operation.

2. The carrier substrate as recited in claim 1, further comprising mirrors (80) coupled to the upper substrate over the openings in the upper substrate.

3. The carrier substrate as recited in claim 1, further comprising heaters (22) formed in contact with the center substrate and configured to heat the center substrate and the frequency conversion elements.

4. The carrier substrate as recited in claim 3, further comprising sensors (24) formed in contact with the center substrate and configured to provide feedback for controlling temperature using the heaters.

5. The carrier substrate as recited in claim 4, wherein the heaters, the sensors and the laser dies are electrically coupled to the lower substrate by a patterned conductor (50).

6. The carrier substrate as recited in claim 1, wherein the center substrate (20) includes glass.

7. The carrier substrate as recited in claim 1, wherein the upper and lower substrates (30, 32) include silicon.

8. The carrier substrate as recited in claim 1, wherein the openings (40, 42) in the upper and lower substrates include a pitch having lithographic tolerances on their position.

9. A method for fabricating a carrier substrate with laser sources, comprising:
bonding (206) an upper substrate to a first side of a transparent center substrate and a lower substrate to a second side of the center substrate opposite the first side;
forming (208) openings to the center substrate through the upper and lower substrate such that openings correspond on opposite sides of the center substrate;
attaching (212) a frequency conversion element to the center substrate on the first side in the openings; and
aligning (214) a laser die to each frequency conversion element and coupling the laser dies to the lower substrate such that light from the laser dies is communicated through the frequency conversion element and the center substrate.

10. The method as recited in claim 9, further comprising applying (216) mirrors to the upper substrate over the openings in the upper substrate.

11. The method as recited in claim 9, further comprising forming (204) heaters in contact with the center substrate configured to heat the center substrate and the frequency conversion elements.

12. The method as recited in claim 11, further comprising forming (204) sensors in contact with the center substrate configured to provide feedback for controlling temperature using the heaters.

13. The method as recited in claim 9, further comprising patterning (210) a conductive material to enable electrical connections.

14. The method as recited in claim 9, wherein aligning (214) includes viewing a laser die through the center substrate and the frequency conversion element to align the laser die to the frequency conversion element.

15. The method as recited in claim 9, wherein the step of forming (208) openings includes forming the openings in the upper and lower substrates with a pitch having lithographic tolerances on the positions of the openings.

16. The method as recited in claim 9, wherein bonding (206) includes applying adhesive or glue to connect the upper and lower substrates with the center substrate.

17. The method as recited in claim 9, wherein bonding (206) includes applying a low-temperature fusion bonding process.

18. A method for fabricating a carrier substrate with laser sources, comprising:
patterning (204) heaters and sensors of a first side of a transparent center substrate;
bonding (206) a lower substrate to the first side of the center substrate and an upper substrate to a second side of the center substrate opposite the first side;
forming (208) openings to the center substrate through the upper and lower substrates such that openings correspond on opposite sides of the center substrate;
patterning (210) a conductive material to enable electrical connections to the heaters, the sensors and laser dies;
attaching (212) a frequency conversion element to the center substrate on the first side in the openings;
aligning (214) laser dies to each frequency conversion element and coupling the laser dies to the lower substrate such that light from the laser dies is communicated through the frequency conversion element and the center substrate; and
applying (216) mirrors to the upper substrate over the openings in the upper substrate.

19. The method as recited in claim 18, wherein aligning (214) includes viewing a laser die through the center substrate and the frequency conversion element to align the laser die to the frequency conversion element.

20. The method as recited in claim 18, wherein forming (208) openings includes forming the openings in the upper and lower substrates with a pitch having lithographic tolerances on the positions of the openings.

21. The method as recited in claim 18, wherein bonding (206) includes applying adhesive or glue to connect the upper and lower substrates with the center substrate.
